(19) United States
(12) Patent Application Publication
(10) Pub. No.: US 2020/0381468 A1
(43) Pub. Date: Dec. 3, 2020

(54) IMAGE SENSOR, MANUFACTURING METHOD THEREOF AND IMAGING DEVICE

(71) Applicant: HUAIAN IMAGING DEVICE MANUFACTURER CORPORATION, HUAIAN (CN)

(72) Inventors: Haifeng LONG, HUAIAN (CN); Xiaolu HUANG, HUAIAN (CN); Koichi FUJII, HUAIAN (CN); Lingyun NI, HUAIAN (CN)

(73) Assignee: HUAIAN IMAGING DEVICE MANUFACTURER CORPORATION, HUAIAN (CN)

(21) Appl. No.: 16/452,000

(22) Filed: Jun. 25, 2019

(30) Foreign Application Priority Data
May 27, 2019 (CN) 201910443201.1

(51) Int. Cl. H01L 27/146

(52) U.S. Cl. CPC H01L 27/14627; H01L 27/14685; H01L 27/1463

(57) ABSTRACT

An image sensor includes: a pixel, which includes a radiation sensing element, and an isolation structure between adjacent pixels configured to converge radiation propagating in the isolation structure to reduce radiation crosstalk between adjacent pixels.

### CROSS-REFERENCE TO RELATED APPLICATIONS

This application claims priority to Chinese Patent Application No. 201910443201.1, filed on May 27, 2019, which is hereby incorporated by reference in its entirety.

### TECHNICAL FIELD

The present disclosure relates to an image sensor, a manufacturing method thereof and an imaging device.

### BACKGROUND

Image sensors can be used to sense radiation (e.g., light radiation, including but not limited to visible light, infrared light, ultraviolet light, X-ray, etc.) to generate corresponding electrical signals (e.g., images). It is widely used in digital cameras, mobile communication terminals, security facilities and other imaging devices.

Between adjacent pixels in the image sensor, part of the radiation propagating in one pixel may propagate to another pixel, which causes radiation crosstalk and reduces the imaging quality. Therefore, a new technology is needed to reduce radiation crosstalk.

### SUMMARY

One of aims of the present disclosure is to provide a new method of manufacturing a semiconductor device.

One aspect of this disclosure is to provide an image sensor. The image sensor includes: a pixel, the pixel including a radiation sensing element; and an isolation structure between adjacent pixels configured to converge radiation propagating in the isolation structure to reduce radiation crosstalk between adjacent pixels.

Another aspect of this disclosure is to provide an imaging device. The imaging device including the image sensor described above, and a lens for converging external radiation and guiding it to the image sensor.

Another aspect of this disclosure is to provide a method for manufacturing an image sensor including: providing a substrate; forming a radiation sensing element in the substrate; forming a pixel including the radiation sensing element; forming an isolation structure between adjacent pixels, the isolation structure is formed to converge radiation propagating in the isolation structure to reduce the radiation crosstalk between adjacent pixels.

Further features of the present disclosure and advantages thereof will become apparent from the following detailed description of exemplary embodiments with reference to the attached drawings.

### BRIEF DESCRIPTION OF THE DRAWINGS

The accompanying drawings, which constitute a part of the specification, illustrate embodiments of the present disclosure and, together with the description, serve to explain the principles of the present disclosure.

The present disclosure will be better understood according the following detailed description with reference of the accompanying drawings.

FIG. 1 is a schematic cross-sectional view showing an image sensor in some embodiments of the present disclosure.

FIG. 2 is a schematic cross-sectional view showing an image sensor in some embodiments of the present disclosure.

FIG. 3 is a schematic cross-sectional view showing an image sensor in some embodiments of the present disclosure.

FIG. 4 is a schematic cross-sectional view illustrating an image sensor in some embodiments of the present disclosure.

FIG. 5 is a schematic cross-sectional view illustrating an image sensor in some embodiments of the present disclosure.

FIG. 6 is a schematic cross-sectional view showing an image sensor in some embodiments of the present disclosure.

FIG. 7 is a schematic cross-sectional view showing an image sensor in some embodiments of the present disclosure.

FIG. 8 is a schematic cross-sectional view illustrating an image sensor in some embodiments of the present disclosure.

FIG. 9 is a schematic cross-sectional view showing an image sensor in some embodiments of the present disclosure.

FIG. 10 is a flowchart illustrating a manufacturing method of an image sensor according to some embodiments of the present disclosure.

FIG. 11 is a schematic cross-sectional view showing an image sensor corresponding to some steps of the manufacturing method shown in FIG. 10.

FIG. 12 is a schematic cross-sectional view showing an image sensor corresponding to some steps of the manufacturing method shown in FIG. 10.

FIG. 13 is a schematic cross-sectional view showing an image sensor corresponding to some steps of the manufacturing method shown in FIG. 10.

FIG. 14 is a schematic cross-sectional view showing an image sensor corresponding to some steps of the manufacturing method shown in FIG. 10.

FIG. 15 is a schematic cross-sectional view showing an image sensor corresponding to some steps of the manufacturing method shown in FIG. 10.

Note that, in the embodiments described below, in some cases the same portions or portions having similar functions are denoted by the same reference numerals in different drawings, and description of such portions is not repeated. In some cases, similar reference numerals and letters are used to refer to similar items, and thus once an item is defined in one figure, it need not be further discussed for following figures.

In order to facilitate understanding, the position, the size, the range, or the like of each structure illustrated in the drawings and the like are not accurately represented in some cases. Thus, the disclosure is not necessarily limited to the position, size, range, or the like as disclosed in the drawings and the like.

### DETAILED DESCRIPTION

Various exemplary embodiments of the present disclosure will be described in details with reference to the accompanying drawings in the following. It should be noted that the relative arrangement of the components and steps, the numerical expressions, and numerical values set forth in these embodiments do not limit the scope of the present invention unless it is specifically stated otherwise.

The following description of at least one exemplary embodiment is merely illustrative in nature and is in no way intended to limit this disclosure, its application, or uses. That is to say, the structure and method discussed herein are illustrated by way of example to explain different embodiments according to the present disclosure. It should be understood by those skilled in the art that, these examples, while indicating the implementations of the present disclosure, are given by way of illustration only, but not in an exhaustive way. In addition, the drawings are not necessarily drawn to scale, and some features may be enlarged to show details of some specific components.

Techniques, methods and apparatus as known by one of ordinary skill in the relevant art may not be discussed in detail, but are intended to be regarded as a part of the specification where appropriate.

In all of the examples as illustrated and discussed herein, any specific values should be interpreted to be illustrative only and non-limiting. Thus, other examples of the exemplary embodiments could have different values.

In order to reduce radiation crosstalk between adjacent pixels in an image sensor, the present disclosure proposes setting an isolation structure between adjacent pixels. The isolation structure can converge radiation propagating in the isolation structure so that radiation is concentrated in the isolation structure, thereby reducing radiation crosstalk between adjacent pixels.

FIG. 1 is a schematic cross-sectional view illustrating image sensor 1 of some embodiments of the present disclosure. As shown in FIG. 1, the image sensor 1 includes a first pixel 100 and a second pixel 200. The first pixel 100 includes a first radiation sensing element (e.g., a photosensitive element (e.g., a photodiode)) 103 configured to sense radiation. The second pixel 200 includes a second radiation sensing element (e.g., a photosensitive element (e.g., a photodiode)) 203 configured to sense radiation.

The image sensor 1 further includes an isolation structure 400 located between adjacent pixels, which can converge radiation propagating in the isolation structure 400. In the present disclosure, “convergence”, “converging” or “converge” refers to a change in the direction of propagation of the radiation propagating in an isolation structure between adjacent pixels, such that the radiation will concentrate better in the interior of the isolation structure. But, it does not require that the radiation is focused at a focal point. Because the radiation is centralized to some extent toward the inside of the isolation structure, the radiation propagating in the isolation structure is relatively not easy to propagate to the pixels outside the isolation structure, which can reduce radiation crosstalk.

The material of the isolation structure may include any suitable transparent material, including one or more of metallic oxides, non-metallic oxides, nitrides, fluorides, sulfides, transparent organic materials (such as resins), etc. For example, the transparent material may include one or more of silicon oxide, silicon nitride, AlON, MgO, MgAl₂O₄, CaF, MgF₂, AlN, SiAlON, etc.

In some embodiments, as shown in FIG. 1, the isolation structure 400 is located between radiation sensing elements 103 and 203 of adjacent pixels 100 and 200. In some embodiments, the upper end of the isolation structure 400 is formed as a lens portion 405 with an upwardly convex curved shape of surface. In some embodiments, the lens portion 405 can be formed integrally with the isolation structure 400, for example, by etching the upper end of the isolation structure 400.

In some embodiments, as shown in FIG. 1, the pixels 100 and 200 further include microlenses 101 and 201 located above the radiation sensing element. In some embodiments, the material of the lens portion 405 is the same as that of the microlens 101 or 201. For example, the lens portion 405 can be formed by the same process as that used to form the microlens 101 or 201 (e.g., reflowing or etching of the microlens material).

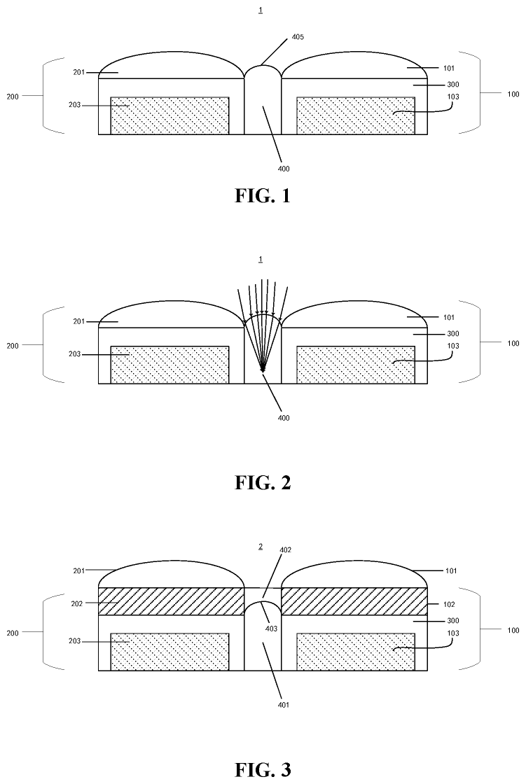

The lens portion 405 at the upper end of the isolation structure 400 between adjacent pixels can converge the external radiation incident from above, which makes it less easy for the radiation to propagate to the pixel 100 or 200 outside the isolation structure 400, thus reducing the radiation crosstalk. FIG. 2 schematically illustrates this convergence effect.

In some embodiments, the width of the lens portion 405 may be less than that of the isolation structure 400. In some embodiments, as shown in FIG. 1, the width of the lens portion 405 may be equal to that of the isolation structure 400. In this case, the lens portion 405 occupies the entire upper end of the isolation structure 400, so that all the external radiation incident from the entire upper end can be converged.

FIG. 3 is a schematic cross-sectional view showing image sensor 2 in some embodiments of the present disclosure. As shown in FIG. 3, compared with the image sensor 2 in FIG. 1, the pixel 100 or 200 further includes a radiation filter 102 or 202 located above the radiation sensing element 103 or 203. In addition, the isolation structure between the pixels 100 and 200 includes a first isolation structure 401 between adjacent radiation sensing elements 103 and 203 and a second isolation structure 402 between adjacent radiation filters 102 and 202, and the second isolation structure 402 being above the first isolation structure 401.

The first isolation structure 401 and the second isolation structure 402 may be formed from the same or different materials. These materials may include any suitable transparent material as described above.

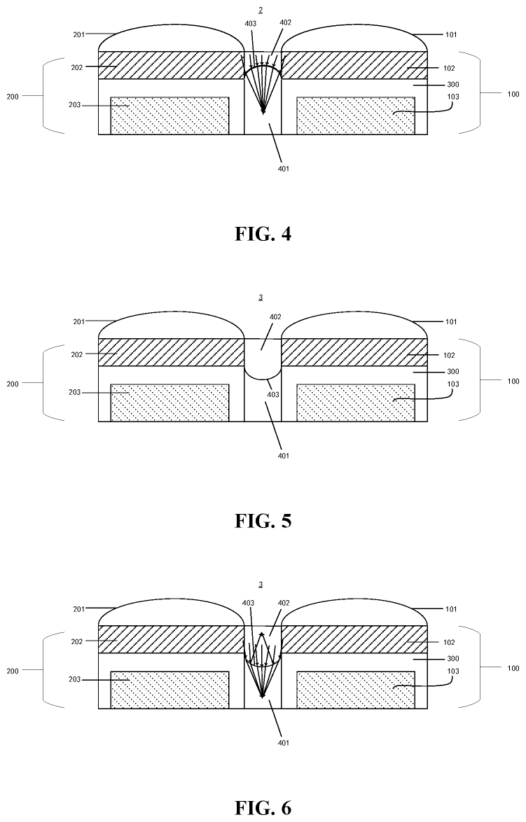

In some embodiments, the first isolation structure 401 and the second isolation structure 402 may be formed by different materials, and the refractive index of the material of the first isolation structure 401 is greater than that of the material of the second isolation structure 402. In this case, the upper end of the first isolation structure 401 is formed as a first lens portion 403 with an upwardly convex curved shape of surface, as shown in FIG. 3. In these embodiments, as shown in FIG. 4, the radiation incident from above (including the radiation propagating from the pixel 100 or 200 adjacent to the second isolation structure 402 to the upper end of the first lens portion 403) enters an optical dense medium from an optical sparse medium, so that the first lens portion 403 can converge the radiation, thereby reducing radiation crosstalk between adjacent pixels.

FIG. 5 is a schematic cross-sectional view showing image sensor 3 in some embodiments of the present disclosure. Compared with the image sensor 2 shown in FIG. 3, in the embodiment shown in FIG. 5, the first isolation structure 401 and the second isolation structure 402 are also formed by different materials, but the refractive index of the material of the first isolation structure 401 is less than that of the material of the second isolation structure 402, and the upper end of the first isolation structure 401 is formed as a first lens portion 403 with a downwardly concave curved shape of surface.

In these embodiments, as shown in FIG. 6, the first lens portion 403 is a concave lens, and since the refractive index of the material of the first isolation structure 401 is less than that of the material of the second isolation structure 402, the radiation incident from above the first lens portion 403 enters an optical sparse medium from an optical dense medium. Therefore, the first lens portion 403 can also converge the radiation incident from above (including the radiation propagating from the pixel 100 or 200 adjacent to the second isolation structure 402 to the upper end of the first lens portion 403), thereby reducing the radiation crosstalk between adjacent pixels.

In addition, in some cases, part of the radiation incident from above the first lens portion 403 may be reflected on the upper surface of the first lens portion 403. In this case, due to the downwardly concave curved shape of surface of the first lens portion 403, the reflected radiation will converge above the first lens portion 403, thus still reducing the radiation crosstalk between adjacent pixels, as shown in FIG. 6.

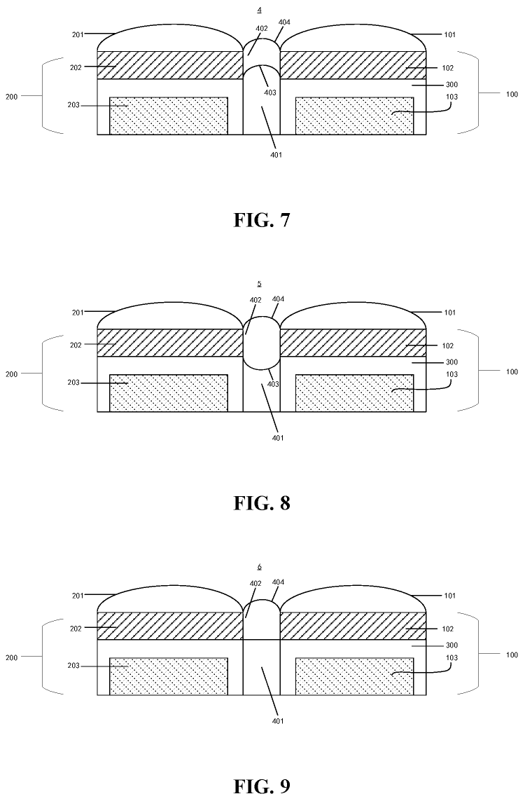

In some embodiments, as shown in the image sensor 4 in FIG. 7 and the image sensor 5 in FIG. 8, the upper end of the second isolation structure 402 can be formed as a second lens portion 404 with an upwardly convex curved shape of surface. In the image sensor 4 shown in FIG. 7, the refractive index of the material of the first isolation structure 401 is greater than that of the material of the second isolation structure 402, and the upper end of the first isolation structure 401 is formed as a first lens portion 403 with an upwardly convex curved shape of surface. In the image sensor 5 shown in FIG. 8, the refractive index of the material of the first isolation structure 401 is less than that of the material of the second isolation structure 402, and the upper end of the first isolation structure 401 is formed as the first lens portion 403 with a downwardly concave curved shape of surface.

In some embodiments, the first lens portion 403 can be formed integrally with the first isolation structure 401, for example, by etching the upper end of the first isolation structure 401. In some embodiments, the second lens portion 404 may be formed integrally with the second isolation structure 402, for example, by etching the upper end of the second isolation structure 402.

In the image sensor shown in FIGS. 7 and 8, both the first lens portion 403 and the second lens portion 404 can converge the radiation incident from above, thus both can reduce the radiation crosstalk between adjacent pixels.

In some embodiments, as shown in the image sensor 6 in FIG. 9, a second lens portion 404 with an upwardly convex curved shape of surface can be formed only at the upper end of the second isolation structure 402, instead of forming a lens portion at the upper end of the first isolation structure 401. In this case, the materials of the first isolation structure 401 and the second isolation structure 402 may be the same or different. In some embodiments, the refractive index of the material of the first isolation structure 401 is greater than that of the material of the second isolation structure 402. In this case, when the radiation propagates from the second isolation structure 402 to the first isolation structure 401, it refracts as the radiation propagates from the light-sparse medium to the light-dense medium, so the propagation direction of the radiation will be somewhat nearer towards the normal line, which also reduces the crosstalk between adjacent pixels.

In some embodiments, as shown in any of FIGS. 7-9, a pixel 100 or 200 may further include a microlens 101 or 201 located above a radiation filter 102 or 202. In this case, the material of the second lens portion 404 may be the same as that of the microlens 101 or 201. For example, the second lens portion 404 may be formed by the same process as that for forming the microlens 101 or 201 (e.g., reflowing or etching of a microlens material).

In some embodiments, the width of the first lens portion 403 may be less than that of the first isolation structure 401. In some embodiments, the width of the first lens portion 403 may be equal to that of the first isolation structure 401. In this case, the first lens portion 403 occupies the entire upper end of the first isolation structure 401, so that all external radiation incident from the entire upper end can converge.

In some embodiments, the width of the second lens portion 404 may be less than that of the second isolation structure 402. In some embodiments, the width of the second lens portion 404 may be equal to that of the second isolation structure 402. In this case, the second lens portion 404 occupies the entire upper end of the second isolation structure 402, so that all external radiation incident from the entire upper end can converge.

It should be pointed out that the width of the first isolation structure 401 and the second isolation structure 402 can be equal or unequal.

In the above embodiment, although the case of forming a lens at the upper end of the isolation structure 400 or the first isolation structure 401 or the second isolation structure 402 is illustrated as an example, a radiation propagation path change element such as a lens can also be formed at other locations of the isolation structure (e.g., the middle, the bottom, the side, etc.). It can be understood by those skilled in the art that radiation crosstalk between adjacent pixels can be reduced as long as the isolation structure can converge the radiation propagating therein and centralize the radiation to a certain extent in the isolation structure, thereby reducing the radiation propagating to the pixels outside the isolation structure.

In some embodiments, radiation sensing elements 103 and 203 can be formed in a substrate 300. Substrate 300 may be composed of suitable one-component semiconductor materials (such as silicon or germanium) or compound semiconductors (such as silicon carbide, silicon germanium, gallium arsenide, gallium phosphide, indium phosphide, indium arsenide and/or indium antimonide) or combinations thereof. In addition, for example, the substrate 300 may use SOI (silicon on insulators) substrate or any other suitable material.

In some embodiments, for example, radiation filters 102 and 202 are formed by adding dyes to transparent materials such as transparent resins. In some embodiments, the first pixel 100 and the second pixel 200 are alternately arranged on the image sensor as a pixel array. In some embodiments, the pixel array is a two-dimensional array. For example, the first pixel 100 and the second pixel 200 can be arranged alternately as a pixel array in an arbitrary array mode such as a Bayer array.

In some embodiments, the present disclosure further includes an imaging device (not shown), which includes any of the various image sensors described above. The imaging device may further include a lens for converging external radiation and guiding it to the image sensor.

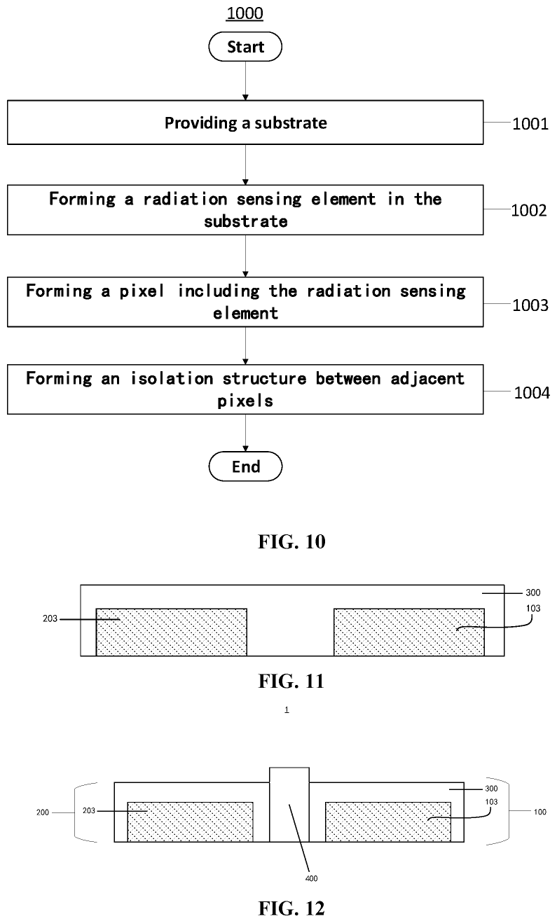

The present disclosure further includes a method 1000 for manufacturing an image sensor. FIG. 10 is a flowchart showing a manufacturing method 1000 of an image sensor according to some embodiments of the present disclosure. FIG. 11-15 schematically illustrate a cross-sectional view of an image sensor corresponding to some steps of the method 1000 shown in FIG. 10. Method 1000 will be illustrated below in conjunction with FIGS. 10 and 11-15.

In step 1001, a substrate is provided, for example, the substrate 300 shown in FIG. 11. Substrate 300 may be composed of suitable one-component semiconductor materials (such as silicon or germanium) or compound semiconductors (such as silicon carbide, silicon germanium, gallium arsenide, gallium phosphide, indium phosphide, indium arsenide and/or indium antimonide) or combinations thereof. In addition, for example, the substrate 300 may use SOI (silicon on insulators) substrate or any other suitable material.

In step 1002, as shown in FIG. 11, the first radiation sensing element 103 and the second radiation sensing element 203 are formed in the substrate 300.

In step 1003, pixels are formed, each of which includes radiation sensing elements (e.g., radiation sensing elements 103 or 203). In step 1004, an isolation structure 400 is formed between adjacent pixels, which can converge radiation propagating in the isolation structure 400, thereby reducing radiation crosstalk between adjacent pixels.

In some embodiments, an isolation structure 400 is formed between radiation sensing elements 103 and 203 of adjacent pixels. In some embodiments, method 1000 may further include forming a lens portion having an upwardly convex curved shape of surface at the upper end of the isolation structure 400. In some embodiments, the lens portion can be formed integrally with the isolation structure 400, for example, by etching the upper end of the isolation structure 400.

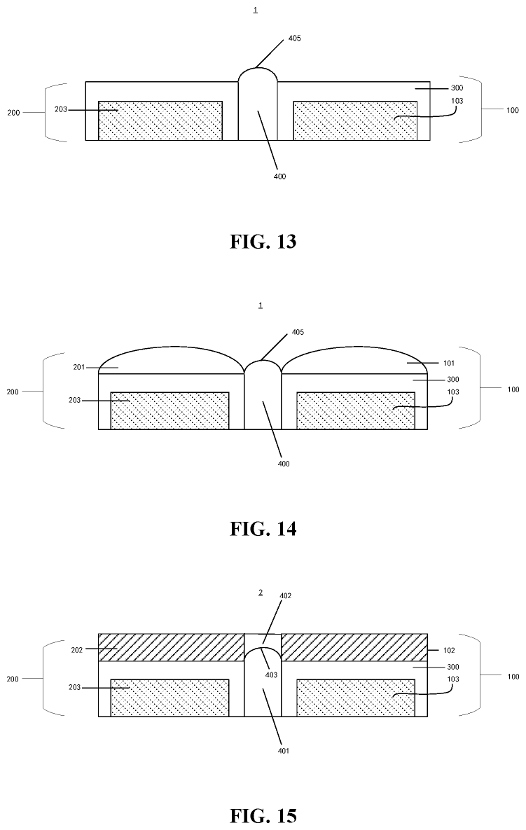

In some embodiments, as shown in FIG. 12, an isolation structure 400 is formed by forming a deep trench isolation (DTI) between radiation sensing elements of adjacent pixels in, for example, a substrate 300. In some embodiments, as shown in FIG. 12, the isolation structure 400 is formed to be higher than the surface of the substrate 300, and then, as shown in FIG. 13, the lens portion 405 is formed by etching the upper end of the isolation structure 400.

Any suitable transparent material can be used to form isolation structures, including one or more of metal oxides, non-metallic oxides, nitrides, fluorides, sulfides, transparent organic materials (such as resins), etc. For example, the transparent material can include one or more of silicon oxide, silicon nitride, AlON, MgO, MgAl₂O₄, CaF, MgF₂, AlN, SiAlON, etc.

In some embodiments, step 1003 for forming a pixel may further include forming a microlens 101 or 201 above the radiation sensing element 103 or 203, as shown in FIG. 14. In some embodiments, the lens portion 405 may be formed by reflowing or etching using the same material as the microlens.

In some embodiments, the lens portion 405 may be formed to have a width equal to that of the isolation structure 400. In this case, the lens portion 405 occupies the entire upper end of the isolation structure 400, so that all external radiation incident from the entire upper end can converge.

Alternatively, in some embodiments, as shown in FIG. 15, step 1003 for forming pixels may further include forming radiation filters 102 and 202 above radiation sensing elements 103 and 203. In some embodiments, the isolation structure can be formed to comprise a first isolation structure 401 between radiation sensing elements 103 and 203 of adjacent pixels and a second isolation structure 402 between radiation filters 102 and 202 of adjacent pixels, the second isolation structure 402 being above the first isolation structure 401. The first isolation structure 401 and the second isolation structure 402 may be formed from the same or different materials. These materials may include any suitable transparent material as described above.

In some embodiments, a first isolation structure 401 is formed by forming a deep trench isolation between radiation sensing elements 103 and 203 of adjacent pixels in, for example, a substrate 300. In some embodiments, a second isolation structure 402 is formed by filling isolation material between adjacent radiation filters 102 and 202.

In some embodiments, the first isolation structure 401 and the second isolation structure 402 may be formed by different materials, and the refractive index of the material of the first isolation structure 401 is greater than that of the material of the second isolation structure 402. In this case, a first lens portion 403 with an upwardly convex curved shape of surface can be formed by etching, for example, the upper end of the first isolation structure 401, as shown in FIG. 15.

In some embodiments, the refractive index of the material of the first isolation structure 401 is less than that of the material of the second isolation structure 402. In this case, a first lens portion 403 with a downwardly concave curved shape of surface can be formed by, for example, etching the upper end of the first isolation structure 401.

In some embodiments, the upper end of the second isolation structure 402 can also be formed as a second lens portion 404 with an upwardly convex curved shape of surface in the image sensor 2 shown in FIG. 15, thereby forming a lens portion at both upper ends of the first isolation structure 401 and the second isolation structure 402. For example, a second lens portion 404 may be formed by etching the upper end of the second isolation structure 402.

Alternatively, in some embodiments, in the image sensor 2 shown in FIG. 15, only the upper end of the second isolation structure 402 can be formed as a second lens portion 404 with an upwardly convex curved shape of surface, while the first lens portion 403 at the upper end of the first isolation structure 401 may not be formed.

In some embodiments, the step 1003 for forming pixels may further include forming microlenses 101 and 201 above radiation filters 102 and 202, as shown in FIG. 5, for example. In this case, a second lens portion 404 may be formed by reflowing or etching using the same material as the microlens 101 or 201.

In some embodiments, the first lens portion 403 may be formed to have a width equal to that of the first isolation structure 401. In this case, the first lens portion 403 occupies the entire upper end of the first isolation structure 401, so that all external radiation incident from the entire upper end can converge.

In some embodiments, the second lens portion 404 may be formed to have a width equal to that of the second isolation structure 402. In this case, the second lens portion 404 occupies the entire upper end of the second isolation structure 402, so that all external radiation incident from the entire upper end can converge.

It should be pointed out that the widths of the first isolation structure 401 and the second isolation structure 402 can be equal or unequal.

The terms “front,” “back,” “top,” “bottom,” “over,” “under” and the like, as used herein, if any, are used for descriptive purposes and not necessarily for describing permanent relative positions. It should be understood that such terms are interchangeable under appropriate circumstances such that the embodiments of the disclosure described herein are, for example, capable of operation in other orientations than those illustrated or otherwise described herein.

The term “exemplary”, as used herein, means “serving as an example, instance, or illustration”, rather than as a “model” that would be exactly duplicated. Any implementation described herein as exemplary is not necessarily to be construed as preferred or advantageous over other implementations. Furthermore, there is no intention to be bound by any expressed or implied theory presented in the preceding technical field, background, summary or detailed description.

The term “substantially”, as used herein, is intended to encompass any slight variations due to design or manufacturing imperfections, device or component tolerances, environmental effects and/or other factors. The term “substantially” also allows for variation from a perfect or ideal case due to parasitic effects, noise, and other practical considerations that may be present in an actual implementation.

In addition, the foregoing description may refer to elements or nodes or features being “connected” or “coupled” together. As used herein, unless expressly stated otherwise, “connected” means that one element/node/feature is electrically, mechanically, logically or otherwise directly joined to (or directly communicates with) another element/node/feature. Likewise, unless expressly stated otherwise, “coupled” means that one element/node/feature may be mechanically, electrically, logically or otherwise joined to another element/node/feature in either a direct or indirect manner to permit interaction even though the two features may not be directly connected. That is, “coupled” is intended to encompass both direct and indirect joining of elements or other features, including connection with one or more intervening elements.

In addition, certain terminology, such as the terms “first”, “second” and the like, may also be used in the following description for the purpose of reference only, and thus are not intended to be limiting. For example, the terms “first”, “second” and other such numerical terms referring to structures or elements do not imply a sequence or order unless clearly indicated by the context.

Further, it should be noted that, the terms “comprise”, “include”, “have” and any other variants, as used herein, specify the presence of stated features, integers, steps, operations, elements, and/or components, but do not preclude the presence or addition of one or more other features, integers, steps, operations, elements, components, and/or groups thereof.

In this disclosure, the term “provide” is intended in a broad sense to encompass all ways of obtaining an object, thus the expression “providing an object” includes but is not limited to “purchasing”, “preparing/manufacturing”, “disposing/arranging”, “installing/assembling”, and/or “ordering” the object, or the like.

Furthermore, those skilled in the art will recognize that boundaries between the above described operations are merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments. However, other modifications, variations and alternatives are also possible. The description and drawings are, accordingly, to be regarded in an illustrative rather than in a restrictive sense.

Although some specific embodiments of the present disclosure have been described in detail with examples, it should be understood by a person skilled in the art that the above examples are only intended to be illustrative but not to limit the scope of the present disclosure. The embodiments disclosed herein can be combined arbitrarily with each other, without departing from the scope and spirit of the present disclosure. It should be understood by a person skilled in the art that the above embodiments can be modified without departing from the scope and spirit of the present disclosure. The scope of the present disclosure is defined by the attached claims.

What is claimed is:

1. An image sensor including:
a pixel comprising a radiation sensing element; and
an isolation structure located between adjacent pixels, configured to converge the radiation propagating in the isolation structure to reduce radiation crosstalk between adjacent pixels.

2. The image sensor according to claim 1,
wherein the isolation structure is located between radiation sensing elements of adjacent pixels, and the upper end of the isolation structure is formed as a lens portion with an upwardly convex curved shape of surface.

3. The image sensor according to claim 2,
wherein the pixel further includes a microlens located above the radiation sensing element, and
the material of the lens portion is the same as that of the microlens.

4. The image sensor according to claim 3,
wherein the width of the lens portion is equal to the width of the isolation structure.

5. The image sensor according to claim 1,
wherein the pixel further includes a radiation filter located above the radiation sensing element, and
the isolation structure includes a first isolation structure between the radiation sensing elements of adjacent pixels and a second isolation structure between the radiation filters of adjacent pixels, and the second isolation structure being above the first isolation structure.

6. The image sensor according to claim 5,
wherein the refractive index of the material of the first isolation structure is larger than that of the material of the second isolation structure, and the upper end of the first isolation structure is formed as a first lens portion with an upwardly convex curved shape of surface.

7. The image sensor according to claim 5,
wherein the refractive index of the material of the first isolation structure is less than that of the material of the second isolation structure, and the upper end of the first isolation structure is formed as a first lens portion with a downwardly concave curved shape of surface.

8. The image sensor according to claim 7,
wherein the upper end of the second isolation structure is formed as a second lens portion with an upwardly convex curved shape of surface.

9. The image sensor according to claim 8,
wherein the pixel further includes a microlens located above the radiation filter, and
the material of the second lens portion is the same as that of the microlens.

10. The image sensor according to claim 7,
wherein the width of the first lens portion is equal to the width of the first isolation structure.

11. The image sensor according to claim 8,
wherein the width of the second lens portion is equal to the width of the second isolation structure.

12. An imaging device comprising:
the image sensor according to claim 1; and
a lens for converging external radiation and guiding it to the image sensor.

13. A method for manufacturing an image sensor comprising:
providing a substrate;
forming a radiation sensing element in the substrate;
forming a pixel including the radiation sensing element; and
forming an isolation structure between adjacent pixels to converge the radiation propagating in the isolation structure, so as to reduce radiation crosstalk between adjacent pixels.

14. The method according to claim 13,
wherein, the isolation structure is formed between radiation sensing elements of adjacent pixels, and
the method further includes:
forming a lens portion with an upwardly convex curved shape of surface at the upper end of the isolation structure.

15. The method according to claim 14, wherein the step for forming the pixel further includes:
forming a microlens above the radiation sensing element, and
wherein the lens portion is formed by reflowing or etching using the same material as the microlens.

16. The method according to claim 13, wherein the step for forming the pixel further includes:
forming a radiation filter above the radiation sensing element, and
wherein the isolation structure includes a first isolation structure between the radiation sensing elements of adjacent pixels and a second isolation structure between the radiation filters of adjacent pixels, and the second isolation structure being above the first isolation structure.

17. The method according to claim 16,
wherein the refractive index of the material of the first isolation structure is larger than that of the material of the second isolation structure, and
the method further includes:
forming the upper end of the first isolation structure as a first lens portion with an upwardly convex curved shape of surface by etching.

18. The method according to claim 16,
wherein the refractive index of the material of the first isolation structure is less than that of the material of the second isolation structure, and
the method further includes:
forming the upper end of the first isolation structure as a first lens portion with a downwardly concave curved shape of surface by etching.

19. The method according to claim 18,
wherein a second lens portion with an upwardly convex curved shape of surface is formed at the upper end of the second isolation structure.

20. The method according to claim 19, wherein the step for forming the pixel further includes:
forming a microlens above the radiation filter, and
wherein the second lens portion is formed by reflowing or etching using the same material as the microlens.
